(19) United States
(12) Patent Application Publication
(10) Pub. No.: US 2016/0099362 A1
(43) Pub. Date: Apr. 7, 2016

(54) System and Method for Deploying Radiation Energy Conversion Cells

(71) Applicants: Kevin Bellette, Hobart (AU); Rodney Austin Green, Forrestfield (AU); Perry Kelly, Gosnells (AU)

(72) Inventors: Kevin Bellette, Hobart (AU); Rodney Austin Green, Forrestfield (AU); Perry Kelly, Gosnells (AU)

(21) Appl. No.: 14/506,648

(22) Filed: Oct. 4, 2014

(51) Int. Cl. H01L 31/048; H01L 31/054; H02S 40/22

(52) U.S. Cl. CPC H01L 31/048; H02S 40/22; H01L 31/0547; H01L 31/0543

(57) ABSTRACT

A radiation energy conversion system comprises: an environmental barrier cover having a barrier cover inner surface; an environmental barrier enclosure supporting the environmental barrier cover, the environmental barrier enclosure having a barrier enclosure internal surface extending to the barrier cover inner surface; a radiation-tranparent optic disposed in at least one of the environmental barrier cover and the environmental barrier enclosure; and at least one radiation energy conversion cell secured to at least one of the barrier enclosure internal surface and the barrier cover inner surface.

### FIELD OF THE INVENTION

The present invention relates to a system and method for deploying radiation energy conversion cells and, more particularly, to a system for providing environmental protection for radiation energy conversion cell systems.

### BACKGROUND OF THE INVENTION

It has been known in the art for some years to deploy and mount solar cells in an open, or exposed, configuration so as to capture the maximum average illumination from the sun over the period of any given day. These solar cells, which are thus subjected to the elements, will typically need cleaning at least quarterly to annually, depending on weather conditions and location around the world that the technology is situated. This typically requires physically washing and brushing the cells to remove deposited contaminants. such as: dust, salt residue (at coastal installations), pollutions, animal discretions, sand, and other materials that may affect the efficiency of the solar technology by blocking or reducing the incident radiation. These contaminants reduce the efficiency of the solar cells beyond the loss of efficiency that is contained within the technology based on the manufacturer's claims. The conventional mounting of the solar cells also reduces efficiency by absorbing thermal energy from the sun. This efficiency reduction can be quite considerable, and may be on the order of about one percent per degree Celsius.

It is thus an object of the present invention to provide, as an alternative to “open to the air” solar cells, radiation energy conversion cells environmentally protected within an internal enclosure.

It is another object of the present invention to directly and indirectly illuminate the radiation energy conversion cells by such means as reflection, refraction, and scattering of the applied incoming illumination within an enclosed structure.

It is another object of the present invention to protect radiation energy conversion cells from the elements by emplacement of the cells in a closed structure.

It is yet another object of the present invention to provide a method of concentrating radiation onto radiation energy conversion cells for achieving optimum conversion efficiency within an internal structure.

It is also an object of the present invention to provide a method of mounting radiation energy conversion cells in various planes and in multiple adjacent layers.

### BRIEF SUMMARY OF THE INVENTION

In one aspect of the present invention, a radiation energy conversion system comprises an environmental barrier cover having a barrier cover inner surface; an environmental barrier enclosure supporting the environmental barrier cover, the environmental barrier enclosure having a barrier enclosure internal surface, the barrier enclosure internal surface extending to the barrier cover inner surface so as to define a closed internal volume; a radiation-transparent optic disposed in at least one of the environmental barrier cover and the environmental barrier enclosure; and at least one radiation energy conversion cell secured to at least one of the barrier enclosure internal surface and the barrier cover inner surface, wherein the at least one radiation energy conversion cell is sized and configured so as to fit within the closed internal volume.

In still another aspect of the present invention, a radiation energy conversion system comprises: an environmental barrier cover having a barrier cover inner surface, the environmental barrier cover including an aperture; a radiation-transparent optic disposed in the aperture; an environmental barrier enclosure supporting the environmental barrier cover, the environmental barrier enclosure having a barrier enclosure internal surface extending to the barrier cover inner surface; and a radiation energy conversion cell secured to the barrier enclosure internal surface.

In still another aspect of the present invention, a method of deploying an array of radiation energy conversion cells comprises: providing an environmental barrier cover having a barrier cover inner surface; providing an environmental barrier enclosure to support the environmental barrier cover, the environmental barrier enclosure having a barrier enclosure internal surface, the barrier enclosure internal surface extending to the barrier cover inner surface; providing an aperture in one of the environmental barrier cover and the environmental barrier enclosure; securing a radiation-transparent optic in the aperture; and attaching the radiation energy conversion cell to one of the barrier enclosure internal surface and the barrier cover inner surface.

The additional features and advantage of the disclosed invention is set forth in the detailed description which follows, and will be apparent to those skilled in the art from the description or recognized by practicing the invention as described, together with the claims and appended drawings.

### BRIEF DESCRIPTIONS OF THE DRAWINGS

The foregoing aspects, uses, and advantages of the present invention will be more fully appreciated as the same becomes better understood from the following detailed description of the present invention when viewed in conjunction with the accompanying figures, in which:

FIG. 1 is a diagrammatical illustration of a radiation energy conversion system including an environmental barrier enclosure and an environmental barrier cover with a radiation transparent optic, in accordance with the present invention;

FIG. 2 is a side cross-sectional diagrammatical view of the radiation energy conversion system of FIG. 1, showing radiation energy conversion cell arrays and a base radiation reflector internal to the environmental barrier enclosure;

FIG. 3 is a top cross-sectional diagrammatical view of the radiation energy conversion system of FIG. 1;

FIG. 4 is a top cross-sectional diagrammatical view of an alternative embodiment of the radiation energy conversion system of FIG. 1 showing layer-stacking of cell arrays;

FIG. 5 is a top diagrammatical view of an alternative embodiment of the radiation energy conversion system of FIG. 1 wherein the environmental barrier enclosure is configured with a hexagonal cross section;

FIG. 6 is a top diagrammatical view of an alternative embodiment of the radiation energy conversion system of FIG. 1, where the environmental barrier enclosure is configured as an inverted truncated pyramid;

FIG. 7 is a side diagrammatical cross-sectional view of an alternative embodiment of the radiation energy conversion system of FIG. 1 wherein the radiation energy conversion cell array is supported on the environmental barrier base;

FIG. 8 is a side diagrammatical cross-sectional view of an alternative embodiment of the radiation energy conversion system of FIG. 7 wherein the system includes two radiation energy conversion cell arrays and a cover having a radiation-transparent optic enclosed within a support ring;

FIG. 9 is a side diagrammatical cross-sectional view of an alternative embodiment of the radiation energy conversion system of FIG. 7 wherein the radiation transparent optic is disposed in the environmental barrier enclosure and the radiation energy conversion cell array is supported by the wall of the environmental barrier enclosure;

FIG. 10 is a side diagrammatical cross-sectional view of an alternative embodiment of the radiation energy conversion system of FIG. 1, the system having individual radiation energy conversion cells supported by the wall of the environmental barrier enclosure with a radiation-transparent cover;

FIG. 11 is a side diagrammatical cross-sectional view of an alternative embodiment of the radiation energy conversion system of FIG. 1, the system configured as an inverted truncated cone, where a radiation energy conversion cell array is attached to the radiation environmental barrier cover; and,

FIG. 12 is an isometric diagrammatical view of a plurality of deployed radiation energy conversion systems and a power station.

### DETAILED DESCRIPTION OF THE INVENTION

The following detailed description is of the best currently contemplated modes of carrying out the invention. The description is not to be taken in a limiting sense, but is made merely for the purpose of illustrating the general principles of the invention.

As used herein, the term “energy collector cell” or “radiation energy conversion cell” refers to a solar, photovoltaic, or other cell technology in which the deployed cell functions to collect incident radiation energy within a specified range of wavelengths, such as solar radiation, and convert the collected radiation energy into electrical current. For example, photovoltaic cells, which function to convert optical light into electrical energy, are included in the definition of an “energy collector cell” or a “radiation energy conversion cell.”

The present invention results from the observation that developing and placing the solar technology within a protective structure results in reduced maintenance, less wear and tear and hence longer useful life than the traditional manufacturers warranties. The purpose of the protective structure is to shield the Energy Collector cells from the effects of air-borne contamination products such as dust, dirt, sand, pollution and other materials that can affect the solar cells. Other costs are also reduced. Insurance premiums, for example, may see a reduction as the solar cells are less likely to be damaged from the ambient environment. Moreover, by emplacing solar cells in an internal structure, the internal structure housing the solar cells serves to reduce the overall space requirement for a solar energy source, in comparison to conventional solar cell deployment configurations.

The disclosed systems are designed to acquire: (i) solar energy and other radiated optical energy from natural sources, or (ii) radiation from an artificial source of Illumination, or (iii) radiation from any other source, and to transmit and concentrate the radiated energy to the surfaces of the Energy Collector Cells within the protective structure.

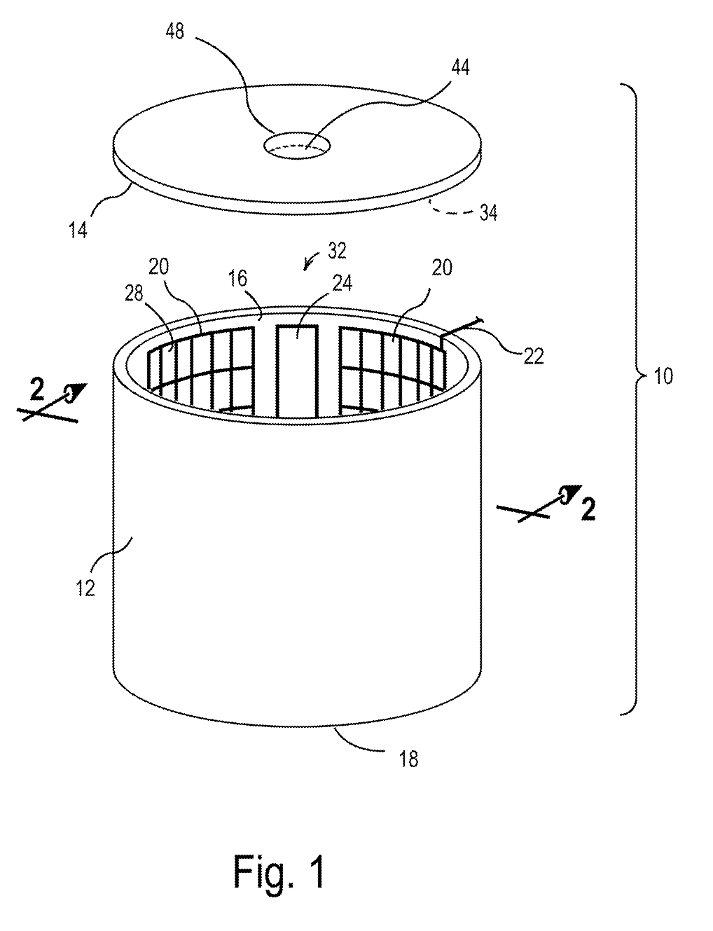

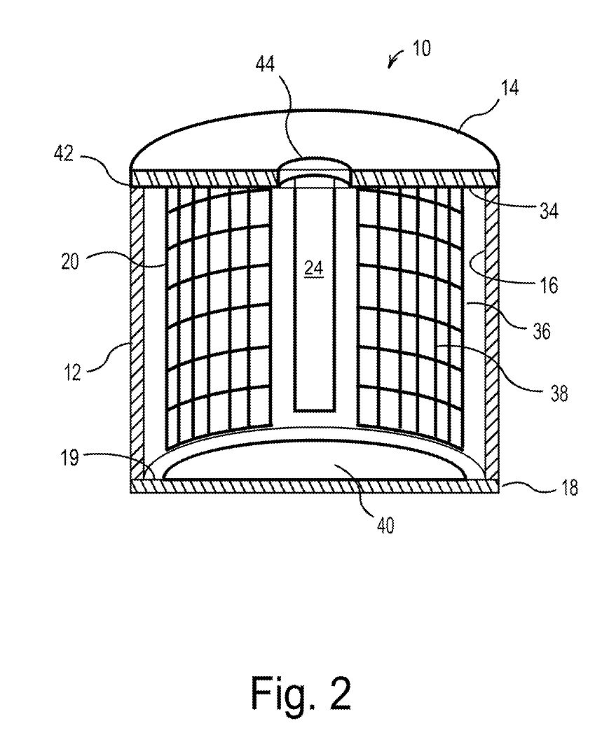

There is shown in FIG. 1 a radiation energy conversion system 10 suitable for converting a portion of the spectrum of incident radiation into electrical current, in accordance with the present invention. The radiation energy conversion system 10 comprises an environmental barrier enclosure 12, and an environmental barrier cover 14. The physical combination of the environmental barrier enclosure 12 and the environmental barrier cover 14 function as the protective internal enclosure described above. Attachment or placement of the environmental barrier cover 14 onto the environmental barrier enclosure 12 defines a closed internal volume 32 bounded by a barrier enclosure internal surface 16, an environmental barrier base surface 19 (shown in FIG. 2), and a barrier cover inner surface 34.

The environmental barrier enclosure 12 shown in the illustration is configured as a cylindrical structure having a generally circular cross section with the non-planar barrier enclosure inner surface 16, and a generally planar environmental barrier base 18. It should be understood that the present invention is not limited to: (i) a protective structure having a circular cross section, or (ii) having a uniform width, or (iii) having a planar base. The environmental barrier enclosure 12 can be of any cross section or shape, having a cross sectional shape alternatively configured as a polygon or an ellipse, for example, depending upon the particular design requirements and emplacement factors.

The environmental barrier base 18 serves to seal off the bottom end of the environmental barrier enclosure 12 from the ambient environment. The environmental barrier base 18 may alternatively have a nonplanar shape such as, for example, having a convex surface, or a concave surface, or any other type of nonplanar surface. It can be appreciated by one skilled in the art that the environmental barrier base 18 may comprise a unitary structure with the environmental barrier enclosure 12, or may be formed as a separate but attached component, as shown in FIG. 2 below.

The environmental barrier cover 14 serves to removably seal off the top end of the environmental barrier enclosure 12 from adverse environmental conditions. The environmental barrier cover 14 includes a cover aperture 48 to provide for the retention or positioning of a radiation-transparent optic 44, such as a lens, or a light conduit, including a plastic or a glass fiber optic cable, to transmit incident radiation into the interior of the radiation energy conversion system 10. The shape of the cover aperture 48 may be circular, as shown, or may comprise another geometric shape.

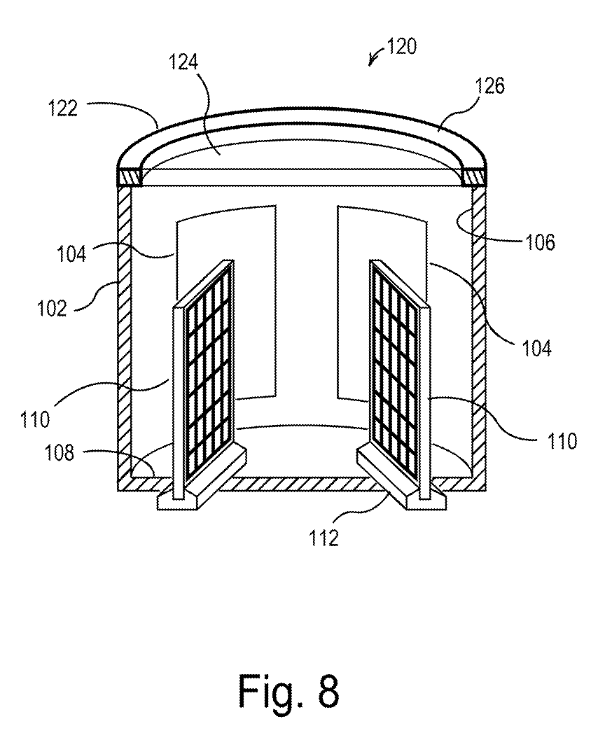

The size of the cover aperture may have a size ranging from less than 0.01 the diameter of the environmental barrier cover 14 to about 0.98 the diameter of the environmental barrier cover 14. Although the location of the radiation-transparent optic 44 is shown in the diagram as positioned in the center of the environmental barrier cover 14, the radiation-transparent optic 44 may be otherwise positioned at any location in the environmental barrier cover 14. In an exemplary embodiment (not shown), the radiation-transparent optic 44 may be mounted inside a structurally-supportive annular ring or frame (shown in FIG. 8), so as to provide a radiation-transparent environmental barrier extending across substantially the entire opening of the environmental barrier enclosure 12.

The radiation-transparent optic 44 thus: (i) allows radiation wavelengths lying within a specified portion of the electromagnetic spectrum to enter the environmental barrier enclosure 12, while (ii) preventing contaminants and particulate matter from migrating into the interior closed volume 32 of the radiation energy conversion system 10. In an exemplary embodiment, a Fresnel lens, a prism, an optic fiber cable (none shown), or any similar type of optical component that is at least partially transmissive to a selected spectral band of radiated energy may be retained within the cover aperture 48.

As shown in the illustration, the radiation energy conversion system 10 comprises at least one radiation energy conversion cell array 20 secured within the closed internal volume 32 of the radiation energy conversion system 10. The method of securing or attachment may include, for example, mechanical components (e.g., brackets, braces, or mechanical fasteners) or chemical compounds (e.g., epoxy or other adhesives), as is well-known in the relevant art. Two radiation energy conversion cell arrays 20 can be seen attached to the barrier enclosure inner surface 16 in the illustration.

It should be understood that additional radiation energy conversion cell arrays 20 may be emplaced in the interior of the environmental barrier enclosure 12, as determined by size of cell array and relevant size and shape criteria for the closed internal volume 32. Basically, the geometric and dimensional criteria for the one or more radiation energy conversion cell arrays 20 is that the one or more radiation energy conversion cell arrays 20 fit inside the closed internal volume 32. It can be appreciated by one skilled in the art that, for a relatively small closed internal volume 32, a single radiation energy conversion cell may be all that can be accommodated within the relatively small closed internal volume 32.

Each radiation energy conversion cell array 20 shown in the diagram comprises a rectangular array of individual energy conversion cells 28, where the energy conversion cell 28 may be a solar cell or a photovoltaic cell, for example. However, the present invention is not limited to such rectangular arrays, and any geometric arrangement of solar cells or photovoltaic cells can be used such as, for example, a hexagonal array. Moreover, each radiation energy conversion cell array 20 can be oriented within the environmental barrier enclosure 12 vertically (as shown), horizontally (not shown), or at various intermediate angles of inclination with respect to the longitudinal axis of the radiation energy conversion system 10.

An electrical cable 22 or equivalent electrical conductors may be provided to transmit electrical current generated by the radiation energy conversion cell array 20 to an external power system (not shown) or to a residential dwelling (not shown). Radiation energy incident on the radiation-transparent optic 44 from an external radiation source (not shown) is thus transmitted through the environmental barrier cover 14 so as to irradiate the internal radiation energy conversion cell arrays 20. One or more optional axial radiation reflectors 24 may be attached to the barrier enclosure inner surface 16 so as to more efficiently scatter the incident radiation onto the surfaces of the radiation energy conversion cell arrays 20. The disclosed configuration of the radiation energy conversion system 10 thus provides environmental protection for the radiation energy conversion cell arrays 20, while simultaneously enabling the energy conversion cells 28 to receive radiation energy.

FIG. 2 is a cross-sectional view of the radiation energy conversion system 10. Each radiation energy conversion cell array 20 may include a rear contact plane 36 that functions in conjunction with front contacts 38 to output electrical current via the electrical cable 22 shown in FIG. 1, as is well known in the relevant art. An environmental seal 42 may be used to prevent entry of contaminants into the radiation energy conversion system 10. The radiation energy conversion system 10 may include an optional base radiation reflector 40 attached to the environmental barrier base surface 19 of the environmental barrier base 18.

Preferably the base radiation reflector 40 is highly reflective to the radiation energy wavelengths to which the radiation energy conversion cell array 20 is most responsive. The base radiation reflector 40 provides for optimal radiation scattering inside the environmental barrier enclosure 12. It can be appreciated by one skilled in the art that the axial radiation reflectors 24 and the base radiation reflector 40 serve to increase the amount of useful incident radiation irradiating the radiation energy conversion cell arrays 20.

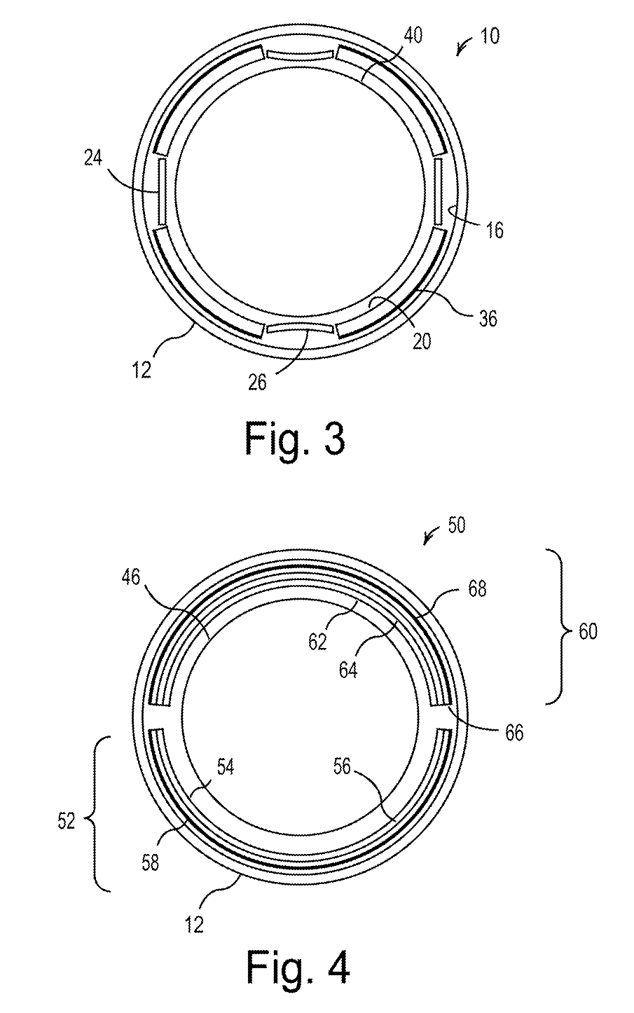

FIG. 3 is a diagrammatical top cross-sectional view of the radiation energy conversion system 10 showing the base radiation reflector 40 disposed between: (i) four radiation energy conversion arrays 20, (ii) two planar axial radiation reflectors 24, and (iii) two convex axial radiation reflectors 26 in the cell array support enclosure 12. Note that the reflecting surface (either front coated surface or rear coated surface) of the planar axial radiation reflector 24 is planar, and that the cylindrical reflecting face (either front or rear) of the convex axial radiation reflector 26 may be curved. It should be understood that the radiation energy conversion system 10 may comprise one or more planar axial radiation reflectors 24, and one or more convex axial radiation reflectors 26, as may be specified by a system designer.

The rear contact plane 36 of each radiation energy conversion array 20 may be positioned adjacent the barrier enclosure inner surface 16. Note that, for clarity of illustration, the support methods are not shown for the four radiation energy conversion arrays 20, the two planar axial radiation reflectors 24, or the two convex axial radiation reflectors 26 in the environmental barrier enclosure 12.

FIG. 4 is a diagrammatical top cross-sectional view of an exemplary embodiment of a radiation energy conversion system 50 showing the base radiation reflector 46 disposed between: (i) a radiation energy conversion array 60, having a multiple layer stacking configuration of solar cell arrays, shown as a three-layer configuration in the example provided, and (ii) a radiation energy conversion array 52, having a two-layer stacking configuration of solar cell arrays. The radiation energy conversion system 50 may include the base radiation reflector 46 that is smaller in diameter than the base radiation reflector 40 used in the radiation energy conversion system 30 shown in FIG. 3.

In the radiation energy conversion system 50, the two-layer radiation energy conversion array 52 includes a first cell array layer 54 disposed on a second cell array layer 56, which in turn is disposed on a rear contact plane 58. The first cell array layer 54 may be sensitive to a first spectral band of incident radiation and is designed to pass a second band of incident radiation with little attenuation. The second cell array layer 56 receives and is sensitive to the second spectral band of incident radiation.

In the radiation energy conversion system 50, the three-layer radiation energy conversion array 60 includes a third cell array layer 62 disposed on a fourth cell array layer 64. The fourth cell array layer 64 is disposed on a fifth cell array layer 66, which in turn is disposed on a rear contact plane 68. The third cell array layer 62 may be sensitive to a third spectral band of incident radiation, and may pass fourth and fifth spectral bands of incident radiation with little attenuation. The fourth cell array 64 may be sensitive to the fourth spectral band of incident radiation, and may pass the fifth spectral band of incident radiation. The fifth cell array layer 66 may be sensitive to the fifth spectral range of incident radiation. It can be appreciated by one skilled in the art that, when the radiation energy conversion system 50 operates using the three-layer radiation energy conversion array 60, this configuration enables the absorption of a greater range of wavelengths for energy collection, and thus serves to improve efficiency of the overall radiation energy conversion system 50.

The radiation energy conversion system 50 further includes a circular environmental barrier cover (not shown), similar to the environmental barrier cover 14 shown above in FIGS. 1 and 2. The radiation transparent optic 44 (shown in FIGS. 1 and 2) is transmissive to the first spectral range of incident radiation, the second spectral range of incident radiation, the third spectral range of incident radiation, the fourth spectral range of incident radiation, and the fifth spectral range of incident radiation. The radiation energy conversion system 50 may include a base radiation reflector 46, where the base radiation reflector 46 is in turn reflective to one or more of the first, second, third, fourth, and fifth ranges of incident radiation.

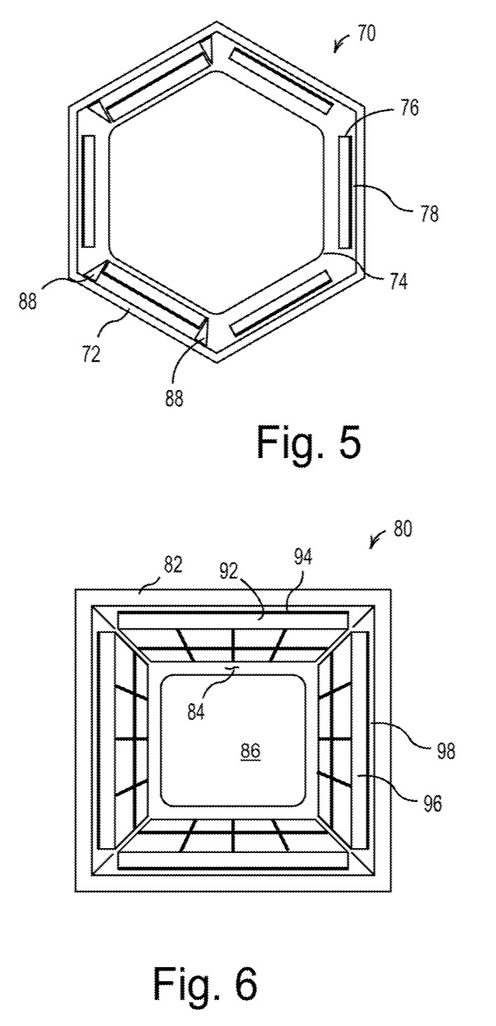

FIG. 5 shows a radiation energy conversion system 70 comprising a, environmental barrier enclosure 72 configured in a regular hexagonal cross section. This allows for closely-spaced and efficiently emplaced multiple radiation energy conversion systems 70 on the ground or on a similar surface, at or below ground level. The radiation energy conversion system 70 includes six radiation energy conversion cell arrays 76 with respective rear contact planes 78.

The radiation energy conversion cell arrays 76 may be mounted to the environmental barrier enclosure 72 using a mounting brackets 88 at each of two ends of the radiation energy conversion cell arrays 76, as shown. The radiation energy conversion cell arrays 76 may be fixed, slideable, or removeable with respect to the mounting brackets 88, whereas the mounting brackets may be essentially permanently secured or fixed to the environmental barrier enclosure 72. The radiation energy conversion system 70 may also include a hexagonal-shaped base radiation reflector 74, or the reflector may alternatively be round or any other geometric shape.

FIG. 6 shows a radiation energy conversion system 80 configured in an inverted truncated pyramid shape with a rectangular cross section. The radiation energy conversion system 80 includes an environmental barrier cover (not shown for clarity of illustration) similar to the environmental barrier cover 14, except for being configured in a rectangular shape. An environmental barrier enclosure 82 may be closed off with a rectangular support enclosure base 84. The environmental barrier enclosure 82 is tapered along an axial direction such that the support enclosure base 84 is smaller in width and length than the environmental barrier cover.

The environmental barrier enclosure 82 may also include a substantially rectangular base radiation reflector 86. Two radiation energy conversion cell arrays 92 (having rear contact planes 94) and two radiation energy conversion cell arrays 96 (having rear contact planes 98) are shown mounted to the inside surface of the cell array support enclosure 82. In an alternative exemplary embodiment, the radiation energy conversion system 80 is not truncated, and the pyramid shape includes an end without the rectangular support enclosure base 84.

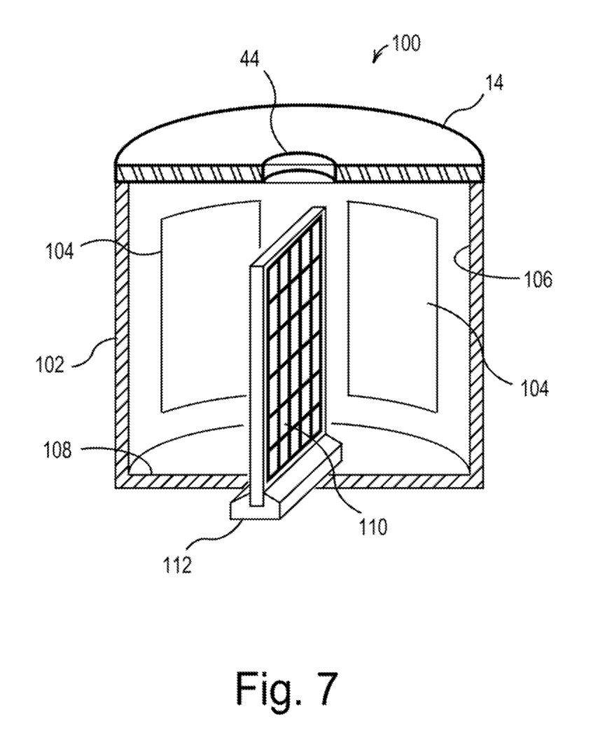

A radiation energy conversion system 100, shown in FIG. 7, comprises an environmental barrier enclosure 102 and the environmental barrier cover 14. One or more axial radiation reflectors 104 may be disposed on an interior surface 106 of the environmental barrier enclosure 102. One or more radiation energy conversion cell arrays 110 may each have one end removably attached to a respective cell array base support 112 and emplaced on an environmental barrier base 108. The base supports 112 are attached to the support enclosure base 108.

In an alternative embodiment, shown in FIG. 8, a radiation energy conversion system 120 may comprise the environmental barrier enclosure 102 and enclose two or more radiation energy conversion cell arrays 110, each secured to a respective base support 112. An environmental barrier cover 122 may comprise a relatively large radiation transparent optic 124 secured within an annular support ring 126. One or more axial radiation reflectors 104 may be mounted on the interior surface 106.

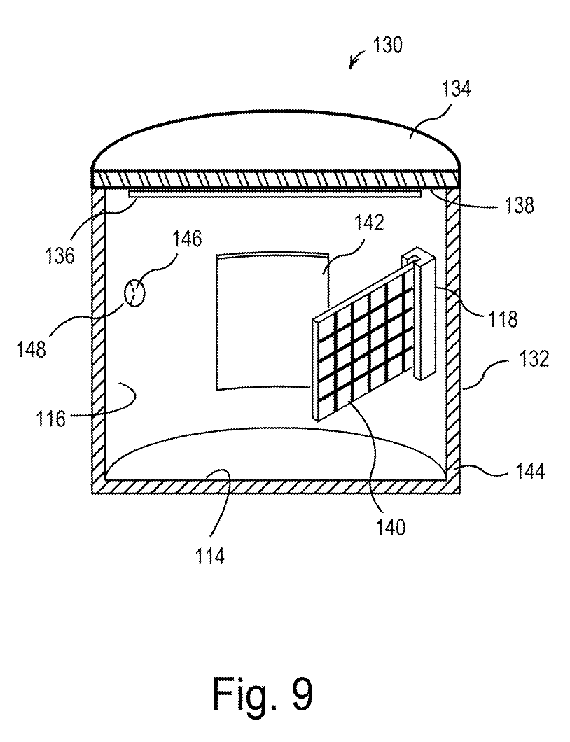

In yet another alternative embodiment, shown in FIG. 9, a radiation energy conversion system 130 may comprise an environmental barrier enclosure 132 and an environmental barrier cover 134 having no aperture, unlike the radiation energy conversion systems described above. A radiation reflector 136 may be disposed on an interior surface 138 of the barrier cover 134, essentially as shown. In this embodiment, a radiation energy conversion cell array 140 is disposed on the barrier enclosure inner surface 116.

As shown in the illustration, one end of the radiation energy conversion cell array 140 may be removably secured to an array support 118, such as by slidably securing the radiation energy conversion cell array 140 within a channel-like configuration as shown, for example. The array support 118 is mounted against and attached to a surface that is substantially normal to the environmental barrier base 114. That is, support for the radiation energy conversion cell array 140 may be provided by an inner wall portion of the barrier enclosure inner surface 116 of the environmental barrier enclosure 132.

The radiation energy conversion cell array 140 (i) may have a substantially vertical orientation as shown, or (ii) may be positioned at an angle to a central axis of the environmental barrier enclosure 132 as may be specified by a system designer. Incident radiation may be conveyed into the environmental barrier enclosure 132 via a radiation transparent optic 146 secured in an aperture 148 in the environmental barrier enclosure 122, the aperture 148 shaped and sized so as to retain the radiation transparent optic 146 in position. Alternatively, the radiation transparent optic 146 and the aperture 148 may be disposed in the barrier cover 134, similar to the configuration of the environmental barrier cover 14 shown in FIG. 1.

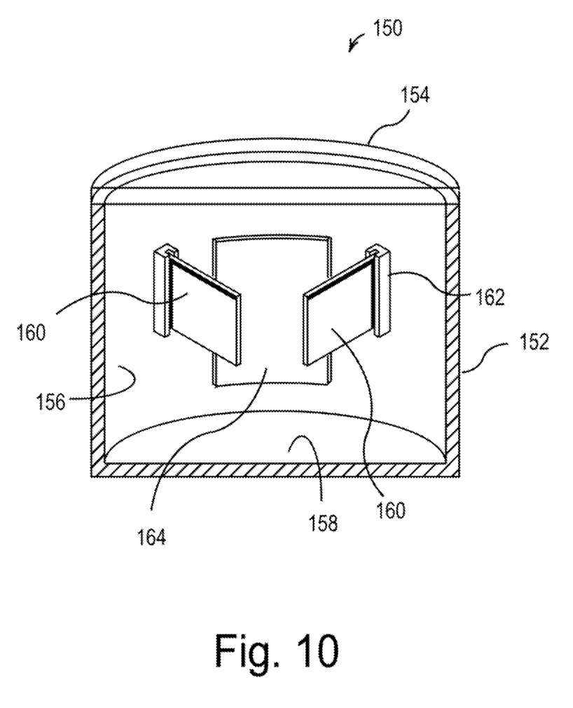

In yet another alternative embodiment, shown in FIG. 10, a radiation energy conversion system 150 may comprise an environmental barrier enclosure 152 and an environmental barrier cover 154 comprising radiation transparent material. A radiation reflector 164 may be disposed on an interior surface 156 of the environmental barrier enclosure 152, essentially as shown. In this embodiment, two radiation energy conversion cells 160 are secured in wall mountings 162 disposed on the barrier enclosure inner surface 156. Alternatively, the two radiation energy conversion cells 160 may be secured to an environmental barrier base 158.

In general, the internal structure of an environmental barrier enclosure can be of any specified geometric cross section or shape such as, for example, round, rectangular, and tapered, as exemplified in the above examples. Moreover, the internal structure of an environmental barrier enclosure may transition from one cross section configuration to another configuration over the length or height of the environmental barrier enclosure. In addition, the environmental barrier enclosure may comprise several disjoint straight and curved segments so as to accommodate the environmental barrier enclosure in physically awkward situations, or as may be specified in accordance with system design requirements.

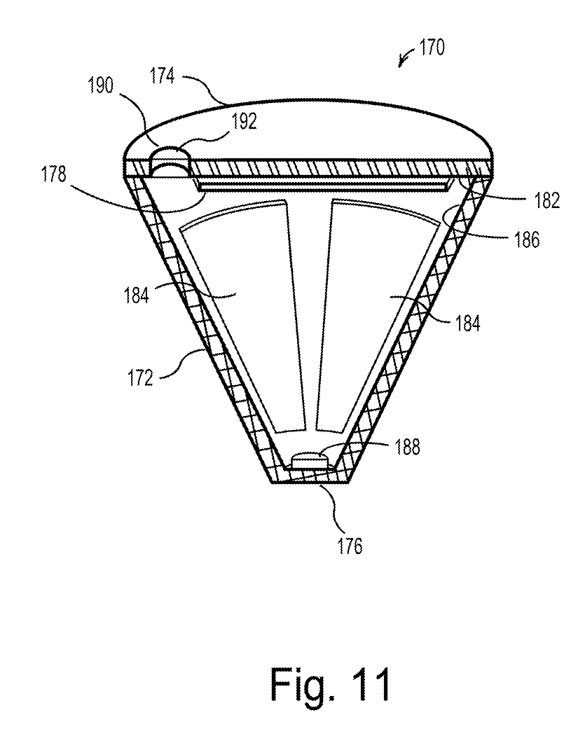

FIG. 11 shows a radiation energy conversion system 170 comprising an environmental barrier enclosure 172 configured in an inverted conical shape with a substantially round cross section. In the exemplary embodiment shown, the conical environmental barrier enclosure 172 is truncated at one end, such that the environmental barrier enclosure 172 decreases in diameter from the relatively larger diameter of an environmental barrier cover 174 to the relatively smaller diameter of an environmental barrier base 176. For a configuration in which the conical environmental barrier enclosure 172 is not truncated, the conical environmental barrier enclosure 172 will not include the environmental barrier base 176 and will not include a base radiation reflector 188.

A radiation energy conversion cell array 178 may be disposed on an interior surface 182 of the environmental barrier cover 174, essentially as shown. One or more axial radiation reflectors 184 may be secured to an interior surface 186 of the radiation energy conversion system 170. The base radiation reflector 188 may be disposed on the environmental barrier base 176. A cover aperture 190 in the environmental barrier cover 174 may be used to secure a radiation-transparent optic 192, and the radiation-transparent optic 192 may be positioned at a specified distance from the center of the environmental barrier cover 174, as shown, or may be positioned at or near the center of the environmental barrier cover 174 (not shown).

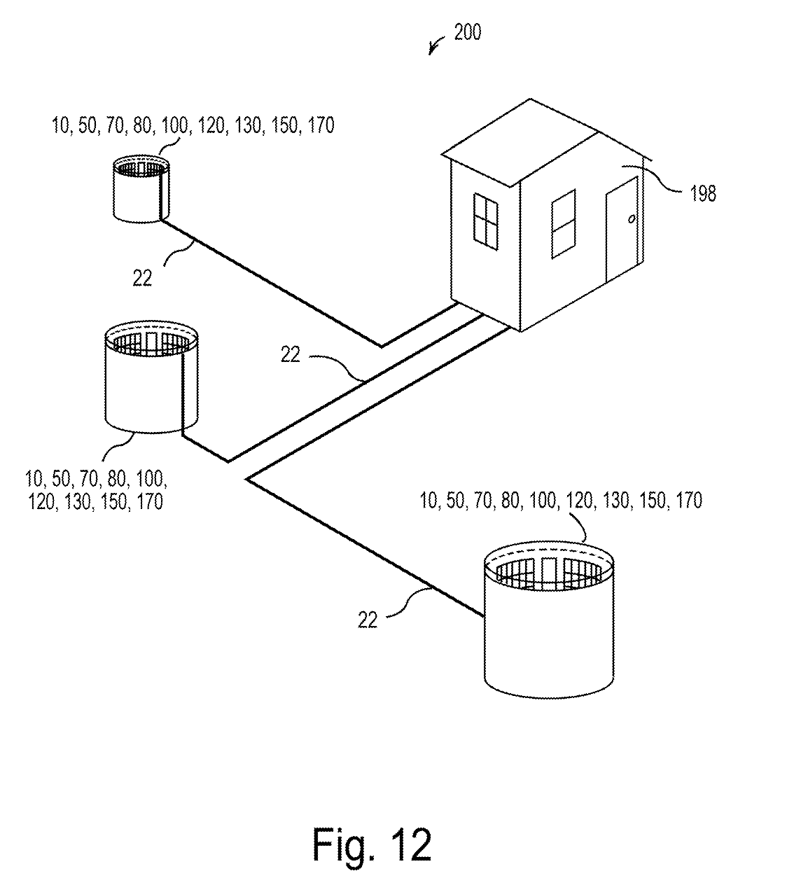

As shown in FIG. 12, a plurality of radiation energy conversion systems 10, 50, 70, 80, 100, 120, 130, 150, 170 may be deployed in an outdoor environment so as to provide generated electrical current, via the respective electrical cables 22, to a central power management facility 198, to a commercial building (not shown), or to a private dwelling (not shown), for example. As can be appreciated by one skilled in the art, one or more of the radiation energy conversion systems 10, 50, 70, 80, 100, 120, 130, 150, 170 may be partially or wholly sunk into or below the ground

It is to be understood that the description herein is only exemplary of the invention, and is intended to provide an overview for the understanding of the nature and character of the disclosed radiation energy conversion systems. The accompanying drawings are included to provide a further understanding of various features and embodiments of the method and devices of the invention which, together with their description serve to explain the principles and operation of the invention.

What is claimed is:

1. A radiation energy conversion system suitable for converting incident radiation into electrical current, said system comprising:
an environmental barrier cover having a barrier cover inner surface;
an environmental barrier enclosure supporting said environmental barrier cover, said environmental barrier enclosure having a barrier enclosure internal surface, said barrier enclosure internal surface extending to said barrier cover inner surface so as to define a closed internal volume;
a radiation-transparent optic disposed in at least one of said environmental barrier cover and said environmental barrier enclosure; and
at least one radiation energy conversion cell secured to at least one of said barrier enclosure internal surface and said barrier cover inner surface, wherein said at least one radiation energy conversion cell is sized and configured so as to fit within said closed internal volume.

2. The system of claim 1 wherein said at least one radiation energy conversion cell forms part of a radiation energy conversion cell array.

3. The system of claim 2 wherein said radiation energy conversion cell array comprises a plurality of solar cells.

4. The system of claim 1 further comprising a radiation reflector disposed on at least one of said barrier enclosure internal surface and said barrier cover inner surface.

5. The system of claim 1 wherein said environmental barrier enclosure comprises one of a circular cylindrical shape, a rectangular cylindrical shape, and a hexagonal cylindrical shape.

6. The system of claim 1 wherein said environmental barrier enclosure comprises one of a circular conical shape, a truncated circular conical shape, a rectangular pyramid shape, and a truncated rectangular pyramid shape.

7. The system of claim 1 further comprising an aperture in one of said environmental barrier cover and said environmental barrier enclosure, said aperture sized and shaped so as to retain said radiation-transparent optic in said one of said environmental barrier cover and said environmental barrier enclosure.

8. The system of claim 7 wherein said radiation-transparent optic comprises one of a lens, a prism, and an optical fiber, said radiation-transparent optic secured within said aperture.

9. A radiation energy conversion system suitable for converting incident radiation into electrical current, said system comprising:
an environmental barrier cover having a barrier cover inner surface, said environmental barrier cover including an aperture;
a radiation-transparent optic disposed in said aperture;
an environmental barrier enclosure supporting said environmental barrier cover, said environmental barrier enclosure having a barrier enclosure internal surface extending to said barrier cover inner surface; and
a radiation energy conversion cell secured to said barrier enclosure internal surface.

10. The system of claim 9 wherein one end of said radiation energy conversion cell is removably secured in a support, said support being attached to said barrier enclosure internal surface.

11. The system of claim 9 further comprising a plurality of said radiation energy conversion cells, said plurality of said radiation energy conversion cells attached to said radiation energy conversion cell to form an array of radiation energy conversion cells.

12. The system of claim 9 wherein two ends of said radiation energy conversion cell array are removably secured in a mounting brackets, said mounting brackets being attached to said barrier enclosure internal surface.

13. A method of deploying a radiation energy conversion cell, said method comprising the steps of:
providing an environmental barrier cover having a barrier cover inner surface;
providing an environmental barrier enclosure to support said environmental barrier cover, said environmental barrier enclosure having a barrier enclosure internal surface, said barrier enclosure internal surface extending to said barrier cover inner surface;
providing an aperture in one of said environmental barrier cover and said environmental barrier enclosure;
securing a radiation-transparent optic disposed in said aperture; and
attaching the radiation energy conversion cell to one of said barrier enclosure internal surface and said barrier cover inner surface.

14. The method of claim 13 further comprising the step of attaching the radiation energy conversion cell to a plurality of radiation energy conversion cells so as to form a radiation energy conversion cell array disposed within a closed internal volume defined by said environmental barrier enclosure and said environmental barrier cover.

15. The method of claim 13 further comprising the step of attaching a radiation reflector to at least one of said barrier enclosure internal surface and said barrier cover inner surface.

16. The method of claim 13 wherein said step of attaching comprises the steps of:
removably securing an end of a radiation energy conversion cell to a bracket; and
attaching said bracket to at least one of said barrier enclosure internal surface and said barrier cover inner surface.
